(19) United States
(12) Patent Application Publication
(10) Pub. No.: US 2026/0076015 A1
(43) Pub. Date: Mar. 12, 2026

(54) SUBSTRATE AND LIGHT-EMITTING DEVICE

(71) Applicant: NICHIA CORPORATION, Anan-shi (JP)

(72) Inventor: Eiko MINATO, Anan-shi (JP)

(73) Assignee: NICHIA CORPORATION, Anan-shi (JP)

(21) Appl. No.: 19/322,707

(22) Filed: Sep. 9, 2025

(30) Foreign Application Priority Data
Sep. 11, 2024 (JP) 2024-157214

(51) Int. Cl. H10H 29/85; H10H 29/24

(52) U.S. Cl. CPC H10H 29/857; H10H 29/24

(57) ABSTRACT

A substrate including a base including a primary surface, a conductive member disposed on the primary surface. and a covering member. The conductive member includes a first portion including a first conductive layer and an aluminum layer layered in order from a bottom of the conductive member, a second portion including a gold layer on an uppermost surface of the second portion of the conductive member, and a third portion including the gold layer, the first conductive layer, and the aluminum layer layered in order from the bottom of the conductive member. The covering member covers a first boundary, which is a boundary between the first portion and the third portion, and a second boundary, which is a boundary between the second portion and the third portion.

### CROSS-REFERENCE TO RELATED APPLICATIONS

The present application claims priority under 35 U.S.C. § 119 to Japanese Patent Application No. 2024-157214, filed Sep. 11, 2024, the contents of which is hereby incorporated by reference in its entirety.

### BACKGROUND

### 1. Technical Field

The present disclosure relates to a substrate and a light-emitting device.

### 2. Description of Related Art

Japanese Patent Publication No. 2020-065001 discloses a light-emitting device including a layer containing aluminum in an external connection region being a power feeding region from the outside and a layer containing gold in an element mounting region being a mounting region of a light-emitting element.

### SUMMARY

In recent years, there has been an increasing demand for a substrate and a light-emitting device that can ensure connection reliability.

Embodiments of the present disclosure can provide a substrate and a light-emitting device that can improve connection reliability.

According to one aspect of the disclosed technologies, a substrate includes: a base including a primary surface; a conductive member disposed on the primary surface; and a covering member, the conductive member including: a first portion including a first conductive layer and an aluminum layer layered in order from the bottom; a second portion including a gold layer on an uppermost surface; and a third portion including the gold layer, the first conductive layer, and the aluminum layer layered in order from the bottom, wherein the covering member covers a first boundary, which is a boundary between the first portion and the third portion, and a second boundary, which is a boundary between the second portion and the third portion.

According to one aspect of the disclosed technologies, a substrate includes: a base including a primary surface; and a conductive member disposed on the primary surface, the conductive member including: a first portion including a first conductive layer and an aluminum layer layered in order from the bottom; a second portion including a gold layer on an uppermost surface; and a third portion including the gold layer, the first conductive layer, and the aluminum layer layered in order from the bottom, and in top view, an area of the third portion is smaller than an area of the first portion, wherein the conductive member includes a second conductive layer including a first layer between the gold layer and the base, and a gap is arranged between the first conductive layer and the first layer.

According to one aspect of the disclosed technologies, a light-emitting device includes the substrate and a light-emitting element, wherein the light-emitting element is connected to the gold layer in the second portion.

The present disclosure can provide a substrate and a light-emitting device that can improve connection reliability.

### BRIEF DESCRIPTION OF THE DRAWINGS

A more complete appreciation of embodiments of the invention and many of the attendant advantages thereof will be readily obtained by reference to the following detailed description when considered in connection with the accompanying drawings.

FIG. 1 is a perspective view schematically illustrating a light-emitting device according to a first embodiment.

FIG. 2 is a top view schematically illustrating the light-emitting device according to the first embodiment.

FIG. 3 is a top view schematically illustrating a substrate constituting the light-emitting device according to the first embodiment.

FIG. 4 is a schematic cross-sectional view taken along line IV-IV in FIG. 2.

FIG. 5A is a cross-sectional view schematically illustrating only the substrate according to the first embodiment or the substrate included in the light-emitting device.

FIG. 5B is a top view schematically illustrating a first boundary according to the first embodiment.

FIG. 5C is a top view schematically illustrating a first boundary of a modified example of the first embodiment.

FIG. 6A is a schematic cross-sectional view illustrating a method for manufacturing the substrate included in the light-emitting device according to the first embodiment.

FIG. 6B is a schematic cross-sectional view illustrating the method for manufacturing the substrate included in the light-emitting device according to the first embodiment.

FIG. 6C is a schematic cross-sectional view illustrating the method for manufacturing the substrate included in the light-emitting device according to the first embodiment.

FIG. 6D is a schematic cross-sectional view illustrating the method for manufacturing the substrate included in the light-emitting device according to the first embodiment.

FIG. 6E is a schematic cross-sectional view illustrating the method for manufacturing the substrate included in the light-emitting device according to the first embodiment.

FIG. 6F is a schematic cross-sectional view illustrating the method for manufacturing the substrate included in the light-emitting device according to the first embodiment.

FIG. 6G is a schematic cross-sectional view illustrating the method for manufacturing the substrate included in the light-emitting device according to the first embodiment.

FIG. 7A is a schematic partial cross-sectional view for explaining a manufacturing process of the light-emitting device according to the first embodiment.

FIG. 7B is a schematic partial cross-sectional view for explaining the manufacturing process of the light-emitting device according to the first embodiment.

FIG. 7C is a schematic partial cross-sectional view for explaining the manufacturing process of the light-emitting device according to the first embodiment.

FIG. 7D is a schematic top view for explaining the manufacturing process of the light-emitting device according to the first embodiment.

FIG. 7E is a schematic partial cross-sectional view for explaining the manufacturing process of the light-emitting device according to the first embodiment.

FIG. 8 is a cross-sectional view schematically illustrating a substrate constituting a light-emitting device according to a second embodiment.

FIG. 9A is a schematic cross-sectional view illustrating a method for manufacturing the substrate included in the light-emitting device according to the second embodiment.

FIG. 9B is a schematic cross-sectional view illustrating the method for manufacturing the substrate included in the light-emitting device according to the second embodiment.

FIG. 9C is a schematic cross-sectional view illustrating the method for manufacturing the substrate included in the light-emitting device according to the second embodiment.

FIG. 9D is a schematic cross-sectional view illustrating the method for manufacturing the substrate included in the light-emitting device according to the second embodiment.

FIG. 9E is a schematic cross-sectional view illustrating the method for manufacturing the substrate included in the light-emitting device according to the second embodiment.

FIG. 10 is a schematic enlarged cross-sectional view of region X in FIG. 9A.

### DETAILED DESCRIPTION OF EMBODIMENTS

Hereinafter, a method for manufacturing and a light-emitting device obtained by the method for manufacturing (hereinafter, may be referred to as the “light-emitting device according to the embodiment”) according to the embodiments of the present invention are described with reference to the drawings. Note that, in the following description, terms indicating a specific direction or position (for example, “upper”, “lower”, and other terms including those terms) are used, as necessary. However, the use of those terms is to facilitate understanding of the invention with reference to the drawings, and the technical scope of the present invention is not limited by the meanings of those terms. Portions having the same reference characters appearing in a plurality of drawings indicate identical or equivalent portions or members.

Further, the following embodiments exemplify a light-emitting device and the like for embodying a technical concept of the present invention, but the present invention is not limited to the description below. The dimensions, materials, shapes, relative arrangements, and the like of constituent components described below are not intended to limit the scope of the present invention to those alone, but are intended to provide an example, unless otherwise specified. The contents described in an embodiment can be applied to any of the other embodiments and modified examples. The sizes, the positional relationship, and the like of the members illustrated in the drawings may be exaggerated in order to clarify the explanation. Furthermore, in order to avoid excessive complication of the drawings, a schematic view in which some elements are not illustrated may be used, or an end view illustrating only a cutting surface may be used as a cross-sectional view.

### Light-Emitting Device According to First Embodiment

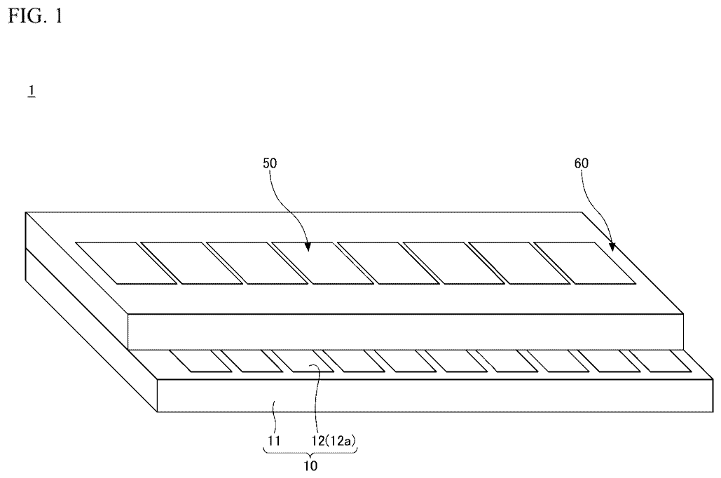

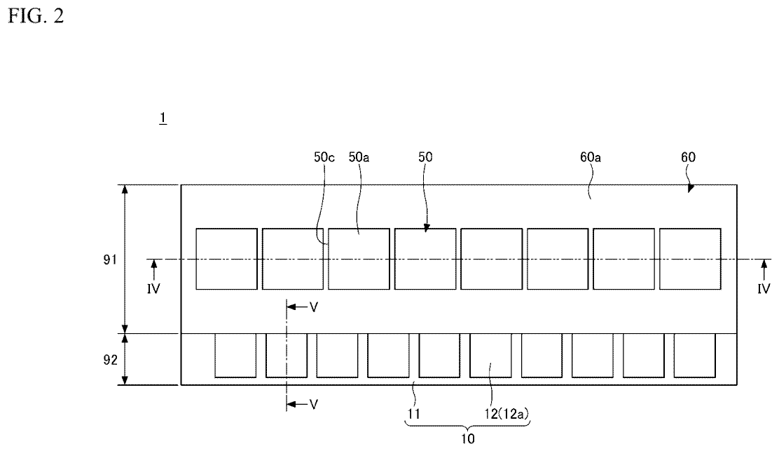

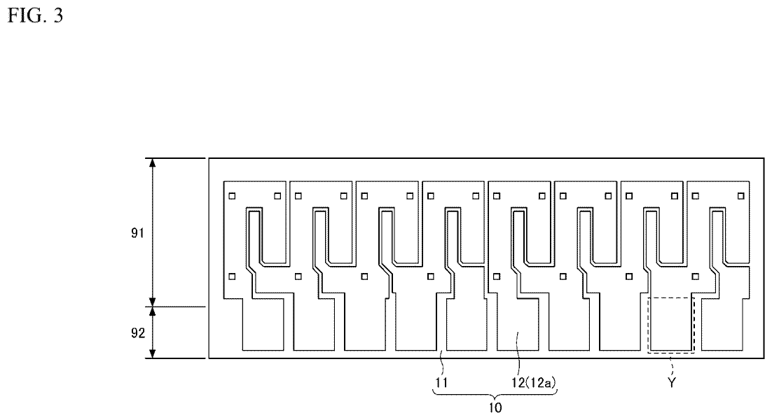

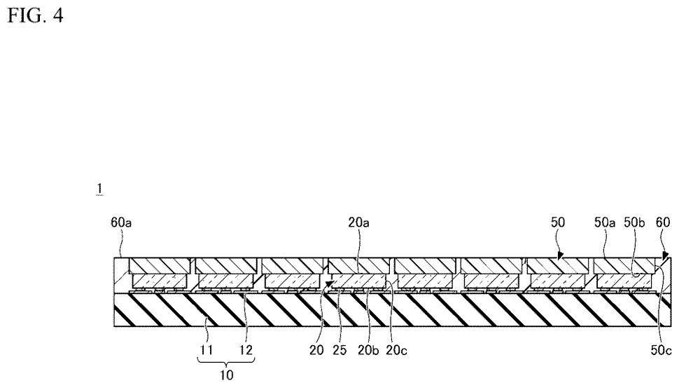

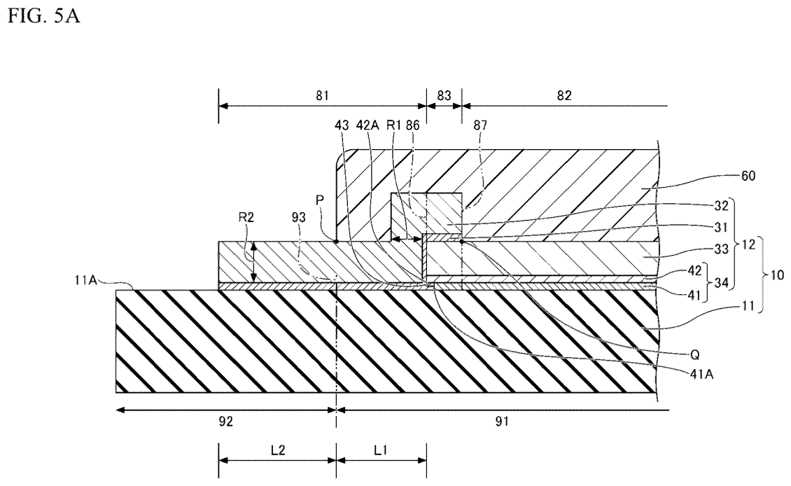

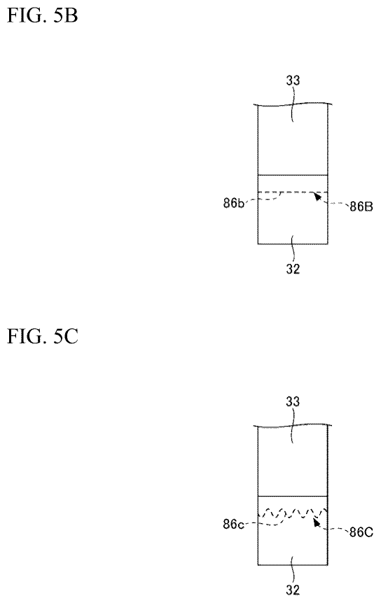

A description is given for the first embodiment. FIG. 1 is a perspective view schematically illustrating a light-emitting device according to the first embodiment. FIG. 2 is a top view schematically illustrating the light-emitting device according to the first embodiment. FIG. 3 is a top view schematically illustrating only a substrate according to the first embodiment or the substrate included in the light-emitting device. FIG. 4 is a schematic cross-sectional view taken along line IV-IV in FIG. 2. FIG. 5A is a cross-sectional view schematically illustrating the substrate constituting the light-emitting device according to the first embodiment, and corresponds to the cross-sectional view taken along line V-V in FIG. 2.

As illustrated in FIGS. 1 to 4 and FIG. 5A, a light-emitting device 1 according to the first embodiment includes a substrate 10 and a light-emitting element 20. The substrate 10 includes a base 11 having a primary surface 11A and a conductive member 12 disposed on the primary surface 11A. The substrate 10 according to the first embodiment further includes a covering member 60 that covers at least a part of the conductive member 12. In the first embodiment, the conductive member 12 is a wiring, and the substrate 10 including the conductive member 12 is a wiring substrate. The primary surface 11A of the base 11 is an upper surface 11A of the base 11. FIG. 3 may illustrate the substrate 10 without the covering member 60. FIG. 5A may illustrate only the substrate 10, or any one of the substrate 10 included in the light-emitting device 1 or the substrate 10 without the covering member 60.

In the first embodiment, the light-emitting device 1 includes a plurality of light-emitting elements 20, and in the light-emitting device 1, the plurality of light-emitting elements 20 can independently emit light.

In the light-emitting device 1, the plurality of light-emitting elements 20 are placed on the substrate 10. The light-emitting element 20 has an upper surface 20a, a plurality of lateral surfaces 20c continuous with the upper surface 20a, and a lower surface 20b on an opposite side to the upper surface 20a. The plurality of lateral surfaces 20c are continuous with the upper surface 20a and the lower surface 20b. In other words, each of the plurality of lateral surfaces 20c has an outer edge continuous with an outer edge of the upper surface 20a and an outer edge of the lower surface 20b. The light-emitting element 20 emits light from the upper surface 20a, the lower surface 20b, and the lateral surfaces 20c.

The light-emitting element 20 has a substantially rectangular upper surface 20a. For example, the light-emitting element 20 has a substantially rectangular parallelepiped or substantially cubic external shape. In this case, the upper surface 20a and the lower surface 20b of the light-emitting element 20 are substantially rectangular, and the light-emitting element 20 has four substantially rectangular lateral surfaces 20c. The upper surface 20a of the light-emitting element 20 can have a polygonal shape such as a triangular shape or a hexagonal shape. The light-emitting element 20 can also have an external shape of a columnar body or a frustum body having a polygonal upper surface.

The light-emitting device 1 further includes a light-transmissive member 50. In the first embodiment, a plurality of light-transmissive members 50 are disposed on the plurality of light-emitting elements 20, respectively. The number of light-transmissive members 50 is, for example, the same as the number of light-emitting elements 20. The distance between adjacent light-transmissive members 50 is in a range from 20 μm to 200 μm, for example. One common light-transmissive member 50 can be disposed on the plurality of light-emitting elements 20. The light-transmissive member 50 has an upper surface 50a, a lower surface 50b on the opposite side to the upper surface 50a, and lateral surfaces 50c between the upper surface 50a and the lower surface 50b. The upper surface 50a of the light-transmissive member 50 serves as a main light-emitting surface of the light-emitting device 1 and constitutes a part of an upper surface of the light-emitting device 1. The lower surface 50b of the light-transmissive member 50 is bonded to the upper surface 20a of the light-emitting element 20. The light-transmissive member 50 and the light-emitting element 20 can be bonded to each other via a light-transmissive adhesive made of a silicone resin or the like disposed between the lower surface 50b of the light-transmissive member 50 and the upper surface 20a of the light-emitting element 20, or the lower surface 50b of the light-transmissive member 50 and the upper surface 20a of the light-emitting elements 20 can be in contact with each other. The light-transmissive member 50 is disposed such that the lower surface 50b of the light-transmissive member 50 is substantially parallel to the upper surface 20a of the light-emitting element 20. The shape of the lower surface 50b of the light-transmissive member 50 is preferably the same as or similar to the shape of the upper surface 20a of the light-emitting element 20. For example, when the upper surface 20a of the light-emitting element 20 has a rectangular shape, the lower surface 50b of the light-transmissive member 50 also preferably has a rectangular shape. The number of light-transmissive members 50 included in the light-emitting device 1 can be smaller than the number of light-emitting elements 20. An example in which the light-emitting device 1 includes a plurality of light-transmissive members, the number of which is smaller than the number of light-emitting elements 20, includes a configuration in which at least one of the plurality of light-transmissive members collectively covers the plurality of light-emitting elements 20.

The lower surface 50b of the light-transmissive member 50 is a flat surface. The upper surface 50a of the light-transmissive member 50 can be a flat surface parallel to the lower surface 50b, or a part or all of the upper surface 50a can have a surface that is not parallel to the lower surface 50b. The lateral surface 50c of the light-transmissive member 50 can be any of a surface perpendicular to the upper surface 50a and/or the lower surface 50b, an inclined surface, a curved surface, and the like. Note that the light-transmissive member 50 can have an uneven structure on a part or all of the surfaces of the light-transmissive member 50.

The lower surface 50b of the light-transmissive member 50 has an area larger than the area of the upper surface 20a of the light-emitting element 20. In this case, the light-transmissive member 50 is preferably disposed so that the lower surface 50b of the light-transmissive member 50 encloses the light-emitting element 20 in top view. The lower surface 50b of the light-transmissive member 50 can have an area smaller than or equal to the area of the upper surface 20a of the light-emitting element 20.

In the light-emitting device 1, the covering member 60 exposes the upper surface 50a of each light-transmissive member 50, and collectively covers the lateral surface 50c of each light-transmissive member 50 and the lateral surface 20c of each light-emitting element 20. The covering member 60 can cover at least a part of the upper surface of the substrate 10. The light-emitting device 1 can further include a protective element mounted on the substrate 10 to protect the light-emitting element 20. The protective element is a Zener diode, for example. When the light-emitting device 1 includes the protective element, the covering member 60 preferably covers an upper surface, a lower surface, and lateral surfaces of the protective element. The covering member 60 can also cover the lower surface 20b of each light-emitting element 20. The covering member 60 is not limited to the above-described embodiment. For example, the covering member 60 can cover only at least a part of the conductive member 12 without contacting the light-emitting element 20.

In the light-emitting device 1, the covering member 60 constitutes the lateral surface of the light-emitting device 1 together with the base 11 of the substrate 10. In the first embodiment, the lateral surface of the covering member 60 and the lateral surface of the base 11 that constitute the lateral surface of the light-emitting device 1 are flush with each other. An upper surface 60a of the covering member 60 and the upper surface 50a of the light-transmissive member 50 that constitute the upper surface of the light-emitting device 1 are flush with each other. The lateral surface of the covering member 60 and the lateral surface of the base 11 may not be flush with each other, and the upper surface 60a of the covering member 60 and the upper surface 50a of the light-transmissive member 50 may not be flush with each other.

The substrate 10 according to the first embodiment includes the base 11 and the conductive member 12 disposed on the primary surface 11A (the upper surface 11A in the first embodiment) of the base 11. Although the case in which the covering member 60 is included in the substrate 10 is described in the first embodiment, the covering member 60 may not be included in the substrate 10. The base 11 supports the conductive member 12. The substrate 10 is a member on which the light-emitting element 20 is placed. The conductive member 12 has an external connecting portion 12a and is used to supply electric power to the light-emitting element 20 from the outside. The substrate 10 can also have a wiring on a lower surface positioned on a side opposite to the upper surface 11A of the base 11.

The base 11 has, for example, a substantially rectangular parallelepiped shape or a substantially cubic shape. The base 11 is preferably made of a material that is less likely to transmit light emitted from the light-emitting element 20, external light, and the like. Examples of the material of the base 11 include ceramics such as aluminum oxide, aluminum nitride, silicon nitride, and mullite, resins such as epoxy resin, silicone resin, modified epoxy resin, urethane resin, phenolic resin, polyimide resin, BT resin, and polyphthalamide, semiconductors such as silicon, metals such as copper and aluminum, a single material of graphite, and composite materials thereof. Among these, ceramics having excellent heat dissipation properties can be suitably used as the material of the base 11. Nitride ceramics are preferable as the material of the base 11. The nitride ceramic is, for example, silicon nitride or aluminum nitride. The thickness of the base 11 is, for example, in a range from 0.1 mm to 0.5 mm in the case of silicon nitride and in a range from 0.3 mm to 2 mm in the case of aluminum nitride. The upper surface 11A of the base 11 includes a first region 91 where the covering member 60 is disposed and a second region 92 exposed from the covering member 60.

The conductive member 12 includes a first portion 81 including a first conductive layer 31 and an aluminum layer 32 layered in order from the bottom, a second portion 82 including a gold layer 33 on the uppermost surface thereof, and a third portion 83 including the gold layer 33, the first conductive layer 31, and the aluminum layer 32 layered in order from the bottom. A first boundary 86, which is a boundary between the first portion 81 and the third portion 83, and a second boundary 87, which is a boundary between the second portion 82 and the third portion 83, are covered with the covering member 60. In the first embodiment, the ionization tendency of the first conductive layer 31 is lower than the ionization tendency of the aluminum layer 32.

The conductive member 12 includes a second conductive layer 34 between the gold layer 33 and the base 11. The second conductive layer 34 includes a first layer 41. In the example illustrated in FIG. 5A, the second conductive layer 34 includes the first layer 41 and a seed layer 42 layered in order from the bottom. The first layer 41 includes nickel and chromium. In the first embodiment, the first layer 41 includes a nickel-chromium alloy. The first layer 41 is disposed on the base 11. The first layer 41 and the base 11 are in contact with each other. A thickness of the first layer 41 is, for example, in a range from 0.025 μm to 0.25 μm. As the seed layer 42, for example, gold can be used. A thickness of the seed layer 42 is, for example, in a range from 0.025 μm to 0.25 μm. A thickness of the second conductive layer 34 is, for example, in a range from 0.05 μm to 0.5 μm. The second conductive layer 34 is disposed only in the second portion 82 and the third portion 83, and is not disposed in the first portion 81. An end portion 41A of the first layer 41 is positioned in the third portion 83, and an end portion 42A of the seed layer 42 is positioned in the first boundary 86. The first layer 41 and the seed layer 42 can include a natural oxide film on the surface thereof and/or the interface thereof. When a natural oxide film is present on the surface and the interface of each of the first layer 41 and the seed layer 42, since the natural oxide film is thin enough to conduct electricity, the first layer 41, the seed layer 42, and the base 11 can be regarded as being in contact with one another.

A natural oxide film is easily formed on the surface of nickel. Nickel also provides good adhesion between ceramics and gold. Chromium provides good adhesion with gold. Therefore, high adhesion is obtained between the first layer 41 including the nickel-chromium alloy and the base 11, and high adhesion is obtained between the first layer 41 including the nickel-chromium alloy and both the seed layer 42, which includes gold, and the gold layer 33.

The gold layer 33 is disposed only in the second portion 82 and the third portion 83, and is not disposed in the first portion 81. A thickness of the gold layer 33 is in a range from 1 μm to 5 μm, for example. The gold layer 33 can include a natural oxide film on the surface thereof. Gold is a soft metal with high electrical conductivity and high thermal conductivity. Therefore, the gold layer 33 has good mountability and connection reliability in flip-chip mounting using gold bumps with respect to the light-emitting element 20.

The first conductive layer 31 is disposed only in the first portion 81 and the third portion 83, and is not disposed in the second portion 82. The first conductive layer 31 includes at least one of titanium or ruthenium. A thickness of the first conductive layer 31 is in a range from 0.05 μm to 0.5 μm, for example. The thickness of the first conductive layer 31 disposed on the lateral surface of the gold layer 33 is smaller than the thickness of the first conductive layer 31 disposed on the upper surface of the gold layer 33 and the upper surface of the base 11. Since the thickness of the first conductive layer 31 disposed on the lateral surface of the gold layer 33 is small, the electrical resistance between the aluminum layer 32 and the gold layer 33 sandwiching the first conductive layer 31 therebetween can be reduced. The first conductive layer 31 and the base 11 are in contact with each other. A gap 43 is arranged between the first conductive layer 31 and the first layer 41. The first conductive layer 31 and the first layer 41 can be in contact with each other or can be separated from each other. When the first conductive layer 31 and the first layer 41 are in contact with each other, the gap 43 is a space surrounded by the first conductive layer 31, the first layer 41, and the seed layer 42. When the first conductive layer 31 and the first layer 41 are separated from each other, the gap 43 is a space surrounded by the first conductive layer 31, the first layer 41, the seed layer 42, and the base 11. A part of the first conductive layer 31 can be positioned in the third portion 83. When the first conductive layer 31 is interrupted as will be described below, the aluminum layer 32 is exposed from the interrupted portion to the gap 43 side, so that the gap 43 can be further surrounded by the aluminum layer 32.

FIG. 5B is a top view schematically illustrating the first boundary of the first embodiment and is an enlarged top view in region Y of FIG. 3. FIG. 5B illustrates the aluminum layer 32 and the gold layer 33 of the conductive member 12. In the example illustrated in FIG. 5B, in a first boundary 86B, which is an example of the first boundary 86, an edge of the gold layer 33 overlapping the aluminum layer 32 in top view has a linear shape. In the first embodiment, in top view, the first boundary 86B substantially overlaps a linear portion 86b that is a line segment connecting two intersection points of the first boundary 86 and the contour of the aluminum layer 32, and the length of the first boundary 86 is substantially equal to the length of the linear portion 86b.

A natural oxide film is easily formed on the surface of titanium and the surface of ruthenium. In addition, titanium and ruthenium have high resistance to halogen, and thus have high resistance to chloride such as sodium chloride containing halogen. Since the first conductive layer 31 including titanium or ruthenium is in contact with the base 11 in which titanium or ruthenium is nitride in the first portion 81, for example, when the conductive member 12 is heat-treated, titanium nitride or ruthenium nitride is formed at an interface between the first conductive layer 31 and the base 11, and high adhesion is obtained between titanium or ruthenium and nitride due to titanium nitride or ruthenium nitride.

The aluminum layer 32 is disposed only in the first portion 81 and the third portion 83, and is not disposed in the second portion 82. The thickness of the aluminum layer 32 is in a range from 1 μm to 10 μm, for example. When the thickness of the aluminum layer 32 is greater than the thickness of the gold layer 33, the difference in height of the upper surface of the aluminum layer 32 caused by the overlap between the aluminum layer 32 and the gold layer 33 in the first portion 81 and the third portion 83 can be reduced, so that the occurrence of an interruption in the aluminum layer 32 can be reduced. The thickness (R1 illustrated in FIG. 5A) of the aluminum layer 32 disposed on the lateral surface of the first conductive layer 31 in a direction parallel to the upper surface 11A of the base 11 is smaller than the thickness (R2 illustrated in FIG. 5A) of the aluminum layer 32 disposed above the gold layer 33 and above the base 11 in contact with the first conductive layer 31 in a direction perpendicular to the upper surface 11A of the base 11. The aluminum layer 32 can include a natural oxide film on the surface thereof. When an aluminum wire is used for bonding, the aluminum layers 32 have excellent bondability to the aluminum wire because the aluminum layers 32 are the same kind of metal.

The first conductive layer 31 and the aluminum layer 32 can each include a natural oxide film on the surface thereof and/or the interface thereof. Since the adhesion between an oxide film of titanium or ruthenium and an oxide film of aluminum is good, the first conductive layer 31 and the aluminum layer 32 have excellent adhesion. When a natural oxide film is present on the surface and the interface of each of the first conductive layer 31 and the aluminum layer 32, since the natural oxide film is thin enough to conduct electricity, the first conductive layer 31 and the aluminum layer 32 can be regarded as being in contact with each other.

In the conductive member 12, a thickness of the third portion 83 is greater than a thickness at an outer edge of the first portion 81 and a thickness of the second portion 82. For example, the thickness of the third portion 83 is greater than the thickness of a portion of the first portion 81 exposed from the covering member 60 and the thickness of the second portion 82.

When a wiring is provided on the lower surface of the base 11, the wiring can include an anode electrode and a cathode electrode electrically connected to an external power supply. Moreover, when the substrate 10 has a wiring on the lower surface of the base 11, a relay wiring for connecting the conductive member 12 and the wiring disposed on the lower surface of the base 11 can be provided on the inside and/or the lateral surface of the base 11. The conductive member 12 can also include a wiring for heat dissipation on the lower surface of the base 11 in addition to an anode electrode and a cathode electrode electrically connected to the light-emitting element 20. For the wiring on the lower surface of the base 11, for example, a metal such as iron, copper, nickel, aluminum, gold, silver, platinum, titanium, tungsten, or palladium, or an alloy including at least one of these metals can be used.

The substrate 10 can include no wiring on the lower surface of the base 11. In this case, an anode electrode and a cathode electrode electrically connected to an external power supply can be disposed on the upper surface or the lateral surface of the base 11.

The substrate 10 can have a recessed portion on the upper surface thereof, and the light-emitting device 1 can have a structure in which the light-emitting element 20 is disposed at the bottom of the recessed portion of the substrate 10.

The substrate 10 can further include an insulating member that covers the base 11 and at least the first portion of the conductive member 12.

Each element constituting the light-emitting device 1 according to the embodiments is described below in detail.

### Light-Emitting Element 20

For the light-emitting element 20, a semiconductor light-emitting element such as a light-emitting diode (LED) chip or a semiconductor laser (LD) chip can be suitably used. Any shape, size, and the like can be selected for the light-emitting element 20. The light-emitting element 20 has, for example, a plurality of electrodes on the lower surface 20b. The light-emitting element 20 is disposed on the substrate 10. The light-emitting element 20 is, for example, flip-chip mounted on the substrate 10 with the lower surface 20b, which includes the electrodes, facing the substrate 10. The plurality of electrodes of the light-emitting element 20 are electrically connected to the conductive member 12. The light-emitting element 20 and the conductive member 12 can be connected using, for example, a known conductive bonding member 25 such as a eutectic solder, a conductive paste, or a bump. Note that regarding the light-emitting element 20 and the conductive member 12, the electrodes of the light-emitting element 20 and the conductive member 12 can be directly bonded without the intervention of the conductive bonding member 25.

The light-emitting element 20 includes, for example, a semiconductor structure and a support substrate supporting the semiconductor structure. The semiconductor structure includes an n-side semiconductor layer, a p-side semiconductor layer, and an active layer interposed between the n-side semiconductor layer and the p-side semiconductor layer. The active layer can have a single quantum well (SQW) structure, or can have a multi quantum well (MQW) structure including a plurality of well layers. The semiconductor structure includes a plurality of semiconductor layers each made of a nitride semiconductor. The nitride semiconductor includes semiconductors having all compositions in which in a chemical formula of InₓAl_{y}Ga_{1-x-y}N (0≤x, 0≤y, and x+y≤1), composition ratios x and y are changed within respective ranges. The light emission peak wavelength of the active layer can be selected as appropriate according to the purpose. The active layer is configured to emit visible light or ultraviolet light, for example.

The semiconductor structure can include a plurality of light-emitting portions each including an n-side semiconductor layer, an active layer, and a p-side semiconductor layer. When the semiconductor structure includes the plurality of light-emitting portions, the plurality of light-emitting portions can each include well layers having different light emission peak wavelengths or well layers having the same light emission peak wavelength. The expression “having the same light emission peak wavelength” includes a case in which there is a variation of several nanometers. The combination of the light emission peak wavelengths of the plurality of light-emitting portions can be selected as appropriate. For example, when the semiconductor structure includes two light-emitting portions, combinations of light emitted from each of the light-emitting portions include a combination of blue light and blue light, a combination of green light and green light, a combination of red light and red light, a combination of ultraviolet light and ultraviolet light, a combination of blue light and green light, a combination of blue light and red light, or a combination of green light and red light. For example, when the semiconductor structure includes three light-emitting portions, the combinations of light emitted from the light-emitting portions include a combination of blue light, green light, and red light. Each of the light-emitting portions can include one or more well layers having light emission peak wavelengths different from the light emission peak wavelengths of other well layers.

The light-emitting element 20 illustrated in FIG. 4 has one semiconductor structure on one support substrate. The one semiconductor structure has only one light-emitting layer. The light-emitting element 20 can have a plurality of semiconductor stacks on the one support substrate. The one semiconductor structure can also have a plurality of light-emitting layers. The structure of the semiconductor structure having a plurality of light-emitting layers can be a structure including a plurality of active layers between one n-side semiconductor layer and one p-side semiconductor layer, or can be a structure in which a structure sequentially including an n-side semiconductor layer, an active layer, and a p-side semiconductor layer is repeated a plurality of times.

In the light-emitting element 20, the plurality of electrodes are disposed on the semiconductor structure. The electrode includes an n-electrode connected to the n-side semiconductor layer and a p-electrode connected to the p-side semiconductor layer. The p-electrode and the n-electrode can be disposed on different surfaces of the semiconductor stack, or can be disposed on the same surface. The plurality of electrodes including the p-electrode and the n-electrode are disposed on the same surface of the semiconductor structure, the side on which the plurality of electrodes are disposed constitutes the lower surface 20b of the light-emitting element 20, and the surface of the support substrate on an opposite side to the surface on which the semiconductor structure is disposed constitutes the upper surface 20a of the light-emitting element 20. Examples of the support substrate include an insulating substrate of sapphire or spinel (MgAl₂O₄), and a nitride-based semiconductor substrate of gallium nitride. In order to extract light emitted from the active layer through the support substrate, the support substrate preferably uses a material having a light-transmissive property. The light-emitting element 20 can include no support substrate. For example, after the semiconductor structure is formed on the support substrate, the support substrate can be removed.

### Light-Transmissive Member 50

The light-transmissive member 50 is a member that is disposed on the light-emitting element 20 and transmits light emitted from the light-emitting element 20 to the outside. The light-transmissive member 50 transmits 60% or more, preferably 70% or more, of light from the light-emitting element 20 and light obtained by converting the wavelength of the light from the light-emitting element 20 by a phosphor to be described below (for example, light having a light emission peak wavelength in a wavelength range from 320 nm to 850 nm). The light-transmissive member 50 can be made of, for example, any of an inorganic material such as glass, ceramics, or sapphire, or an organic material such as a resin or a hybrid resin containing one or more of a silicone resin, a modified silicone resin, an epoxy resin, a modified epoxy resin, an acrylic resin, a phenolic resin, and a fluororesin.

The light-transmissive member 50 can contain a phosphor that can convert the wavelength of at least a part of incident light. Examples of the light-transmissive member 50 containing the phosphor include a sintered body of a phosphor and a material in which phosphor powder is contained in the above-described material. The light-transmissive member 50 can also include a light-transmitting layer such as a resin layer containing a phosphor or a glass layer containing a phosphor formed on a surface of a molded body of resin, glass, or ceramics. The light-transmissive member 50 can also contain a filler such as a light-diffusing material depending on the purpose. When the light-transmissive member 50 contains a filler such as a light-diffusing material, the light-transmissive member 50 can contain a filler in resin, glass, ceramics, or other inorganic materials, or can include a light-transmitting layer such as a resin layer containing a filler or a glass layer containing a filler formed on a surface of a light-transmissive plate that is a molded body of resin, glass, ceramics, or the like.

As the phosphor, an yttrium aluminum garnet-based phosphor (for example, (Y,Gd)₃ (Al,Ga)₅O₁₂:Ce), a lutetium aluminum garnet-based phosphor (for example, Lu₃(Al,Ga)₅O₁₂:Ce), a terbium aluminum garnet-based phosphor (for example, Tb₃(Al,Ga)₅O₁₂:Ce), a CCA-based phosphor (for example, Ca₁₀(PO₄)₆Cl₂:Eu), an SAE-based phosphor (for example, Sr₄Al₁₄O₂₅:Eu), a chlorosilicate-based phosphor (for example, Ca₈MgSi₄O₁₆Cl₂:Eu), a silicate-based phosphor (for example, (Ba,Sr,Ca,Mg)₂SiO₄:Eu), an oxynitride-based phosphor such as a β-SiAlON-based phosphor (for example, (Si,Al)₃ (O,N)₄:Eu) or an α-SiAlON-based phosphor (for example, Ca(Si,Al)₁₂ (O,N)₁₆:Eu), a nitride-based phosphor such as an LSN-based phosphor (for example, (La, Y)₃Si₆N₁₁:Ce), a BSESN-based phosphor (for example, (Ba,Sr)₂Si₅N₈:Eu), an SLA-based phosphor (for example, SrLiAl₃N₄:Eu), a CASN-based phosphor (for example, CaAlSiN₃:Eu), or an SCASN-based phosphor (for example, (Sr,Ca) AlSiN₃:Eu), a fluoride-based phosphor such as a KSF-based phosphor (for example, K₂SiF₆:Mn), a KSAF-based phosphor (for example, K₂(Si₁₋ₓAlₓ)F₆₋ₓ:Mn, where x satisfies 0<x<1), or an MGF-based phosphor (for example, 3.5MgO·0.5MgF₂·GeO₂:Mn), a quantum dot having a perovskite structure (for example, (Cs,FA,MA)(Pb,Sn)(F,Cl,Br,I)₃, where FA and MA represent formamidinium and methylammonium, respectively), a group II-VI quantum dot (for example, CdSe), a group III-V quantum dot (for example, InP), a quantum dot having a chalcopyrite structure (for example, (Ag,Cu)(In,Ga)(S,Se)₂), or the like can be used.

A light-diffusing material known in the art can be used for the light-diffusing material. For example, titanium dioxide, silicon dioxide, aluminum oxide, barium titanate, or the like can be used.

When the light-transmissive member 50 includes a phosphor layer and/or a light-diffusing material layer and a resin is used as a base material for the phosphor layer and the light-diffusing material layer, examples of the resin include thermosetting resins such as an epoxy resin, a modified epoxy resin, a silicone resin, and a modified silicone resin.

### Covering Member 60

The first boundary 86 and the second boundary 87 are covered with the covering member 60. The first boundary 86 is a boundary between the first portion 81 and the third portion 83. The second boundary 87 is a boundary between the second portion 82 and the third portion 83. The light-emitting element 20 is connected to the gold layer 33 in the second portion 82 of the conductive member 12. The light-emitting element 20 is also covered with the covering member 60. The covering member 60 preferably has a light shielding property, and specifically has a light reflecting property and/or a light-absorbing property. In particular, a material that can suitably reflect light emitted from the light-emitting element 20 is preferably contained. For example, the material preferably has a reflectance of 60% or more with respect to light emitted from the light-emitting element 20, and more preferably has a reflectance of 70% or more, 80% or more, or 90% or more.

Since the covering member 60 covers the lateral surface 20c of the light-emitting element 20, light emitted from the lateral surface 20c of the light-emitting element 20 is reflected by the covering member 60. Also, since the covering member 60 covers the lower surface 20b of the light-emitting element 20, light traveling downward from the light-emitting element 20 is reflected by the covering member 60. These can improve the light extraction efficiency in the light-emitting device 1. The covering member 60 can be made of a single resin as will be described below, or can be made of a plurality of different materials including a resin and a light-reflective substance or a light-absorbing substance.

Preferably, the covering member 60 is formed using an insulating material. Examples of the resin used for the covering member 60 include a resin or a hybrid resin containing one or more of a silicone resin, a modified silicone resin, an epoxy resin, a modified epoxy resin, a urea resin, an acrylic resin, a phenolic resin, a bismaleimide triazine resin, a polyphthalamide resin, and a polyimide resin. Among these, it is particularly preferable to use a silicone resin which is excellent in light resistance, heat resistance, and electrical insulation properties and has flexibility. The covering member 60 can also be, for example, a member in which a light-reflective substance or a light-absorbing substance is contained in a light-transmissive resin. Examples of the light-reflective substance include titanium dioxide, silicon dioxide, aluminum oxide, zirconium dioxide, magnesium oxide, potassium titanate, barium titanate, zinc oxide, silicon nitride, aluminum nitride, boron nitride, calcium carbonate, calcium hydroxide, calcium silicate, and combinations thereof. Among these, from the viewpoint of light reflection, titanium oxide having a relatively high refractive index is preferably used. The light-absorbing substance is, for example, carbon black.

In the light-emitting device 1, an aluminum wire can be bonded to the aluminum layer 32 exposed from the covering member 60. In addition, since the gold layer 33 can be used for wiring, the resistance of the wiring can be easily reduced. Moreover, the conductive bonding member 25 has good wettability with respect to the gold layer 33, so that good connection reliability is obtained between the light-emitting element 20 and the gold layer 33.

On the other hand, when the aluminum layer 32 and the gold layer 33 come into contact with each other, galvanic corrosion can occur. Salt water is one of the factors that accelerate galvanic corrosion. However, in the first embodiment, the first conductive layer 31 and the aluminum layer 32 are layered in order from the bottom in the first portion 81, the gold layer 33 is provided on the uppermost surface of the second portion 82, and the gold layer 33, the first conductive layer 31, and the aluminum layer 32 are layered in order from the bottom in the third portion 83. The first boundary 86, which is a boundary between the first portion 81 and the third portion 83, and the second boundary 87, which is a boundary between the second portion 82 and the third portion 83, are covered with the covering member 60. Since the adhesion between the first conductive layer 31 and the base 11 is high, a substance such as salt water is unlikely to enter the substrate 10 through the interface between the first conductive layer 31 and the base 11. Since the adhesion between the first conductive layer 31 and the aluminum layer 32 is also high, a substance such as salt water is unlikely to enter the substrate 10 through the interface between the first conductive layer 31 and the aluminum layer 32. Moreover, even though a substance such as salt water enters the substrate 10 from a point P through an interface between the covering member 60 and the aluminum layer 32, since the third portion 83 is provided between the first portion 81 and the second portion 82, a path to the gold layer 33 indicated by a point Q is long, so that the substance is unlikely to reach the gold layer 33. That is, the aluminum layer 32 and the gold layer 33 can be suppressed from coming into contact with a substance such as salt water and the occurrence of galvanic corrosion can be suppressed. In this way, according to the substrate 10 and the light-emitting device 1, corrosion resistance can be improved. In particular, since the ionization tendency of the first conductive layer 31 is lower than the ionization tendency of the aluminum layer 32, the ionization tendency of the first conductive layer 31 is positioned between the ionization tendency of aluminum and the ionization tendency of gold, so that the occurrence of galvanic corrosion in the aluminum layer 32 is easily reduced.

When the thickness of the third portion 83 is greater than the thickness at the outer edge of the first portion 81 and the thickness of the second portion 82, even though a material such as salt water enters the substrate 10 from the point P through the interface between the covering member 60 and the aluminum layer 32, the material needs to move at least twice in the third portion 83 in the direction substantially perpendicular to the primary surface 11A until the material reaches the gold layer 33 indicated by the point Q. Accordingly, the arrival of the substance such as salt water at the gold layer 33 can be further reduced.

In a case in which the base 11 includes nitride ceramics, and the second conductive layer 34 is disposed between the gold layer 33 and the base 11 and includes nickel and chromium, high adhesion is obtained between the base 11 and the gold layer 33. This is because high adhesion is obtained between the base 11 and the second conductive layer 34, and high adhesion is obtained between the second conductive layer 34 and the gold layer 33.

In the first embodiment, the first conductive layer 31 includes at least one of titanium or ruthenium, and the gap 43 is arranged between the first conductive layer 31 and the first layer 41. Thus, the diffusion of a metal element such as nickel included in the first layer 41 into the first conductive layer 31 can be reduced.

The thickness of the first conductive layer 31 can be smaller or greater than the thickness of the second conductive layer 34, or the thickness of the first conductive layer 31 and the thickness of the second conductive layer 34 can be equal to each other. When the thickness of the first conductive layer 31 is greater than the thickness of the second conductive layer 34, the occurrence of interruption of the first conductive layer 31 in the vicinity of the first boundary 86 due to insufficient film formation or the like is reduced, and film continuity is easily obtained. In the first embodiment, even though the first conductive layer 31 is interrupted in the vicinity of the first boundary 86, since the distance from the end portion of the first conductive layer 31 to the first boundary 86 in the first portion 81 is long, the adhesion between the first conductive layer 31 and the base 11 is high, and the first boundary 86 is covered with the covering member 60, the occurrence of galvanic corrosion can be sufficiently reduced.

When the first conductive layer 31 includes titanium or ruthenium, a natural oxide film is formed on the surface of the first conductive layer 31. A natural oxide film is also formed on the surface of the aluminum layer 32. In this way, since the natural oxide film is formed on the surface of the first conductive layer 31 and the surface of the aluminum layer 32, high adhesion is obtained between the oxide film on the surface of the first conductive layer 31 and the oxide film on the surface of the aluminum layer 32. Moreover, in a case in which the first conductive layer 31 and the base 11 are in contact with each other, when the conductive member 12 is heat-treated, nitride is generated at the interface between the first conductive layer 31 and the base 11 due to titanium or ruthenium included in the first conductive layer 31 and nitrogen included in the base 11. Therefore, high adhesion is obtained between the first conductive layer 31 and the base 11.

In top view, the area of the third portion 83 is preferably smaller than the area of the first portion 81. This makes it possible to reduce the size of the light-emitting device 1 and to easily perform wire bonding on the portion of the first portion 81 exposed from the covering member 60.

In the upper surface 11A of the base 11, a distance L1 between the first boundary 86 and a third boundary 93, which is a boundary between the first region 91 and the second region 92, is preferably 10 μm or more. Thus, in the first portion 81 of the conductive member 12, since the area of the portion covered with the covering member 60 in top view is increased, a substance such as salt water is unlikely to reach the gold layer 33 and the occurrence of galvanic corrosion is reduced, so that the reliability of connection of the light-emitting device 1 can be improved. The distance L1 is more preferably 20 μm or more and even more preferably 30 μm or more. The distance L1 is, for example, 1000 μm or less. Note that the distance L1 is a distance in a direction parallel to the upper surface 11A of the base 11.

In top view, a distance L2 from the third boundary 93 to the outer edge of the first portion 81 is preferably 100 μm or more. This makes it easy to perform wire bonding on the portion of the first portion 81 exposed from the covering member 60. The distance L2 is more preferably 200 μm or more and even more preferably 300 μm or more. The distance L2 is, for example, 1000 μm or less. Note that the distance L2 is a distance in a direction parallel to the upper surface 11A of the base 11.

The light-emitting device 1 can be used for a headlamp of an automobile, for example. When the light-emitting device 1 is used for a head lamp of an automobile, salt water such as rain or fog containing salt can adhere to the light-emitting device 1. Even in such a case, since salt water is unlikely to reach the gold layer 33, the light-emitting device 1 can stably operate for a long period of time and obtain excellent reliability.

### Light-Emitting Device According to Modified Example of First Embodiment

A modified example of the first embodiment is described. The modified example of the first embodiment is different from the first embodiment mainly in the shape of the gold layer 33 in top view. FIG. 5C is a top view schematically illustrating a first boundary of the modified example of the first embodiment.

As illustrated in FIG. 5C, in the modified example of the first embodiment, in a first boundary 86C that is another example of the first boundary 86, an edge of the gold layer 33 overlapping the aluminum layer 32 in top view has a wavy line shape. That is, the first boundary 86C includes one or more curved portions 86c having a curved shape in top view. In top view, the curved portion 86c included in the first boundary 86C includes a point separated from the linear portion 86b connecting two intersection points of the first boundary 86B and the contour of the aluminum layer 32 as illustrated in FIG. 5B, and is longer than the linear portion 86b.

In the modified example of the first embodiment, the gold layer 33 and the first conductive layer 31 are in contact with each other in an area larger than that in the first embodiment, and accordingly, the first conductive layer 31 and the aluminum layer 32 are in contact with each other in an area larger than that in the first embodiment. Therefore, disconnection between the gold layer 33 and the aluminum layer 32 can be reduced, and connection reliability can be improved.

### Method for Manufacturing Light-Emitting Device According to First Embodiment

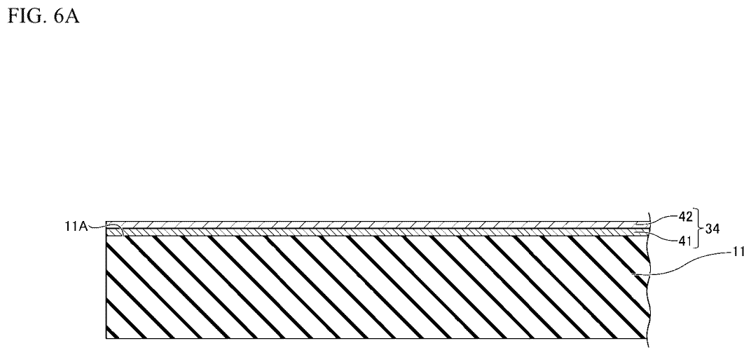

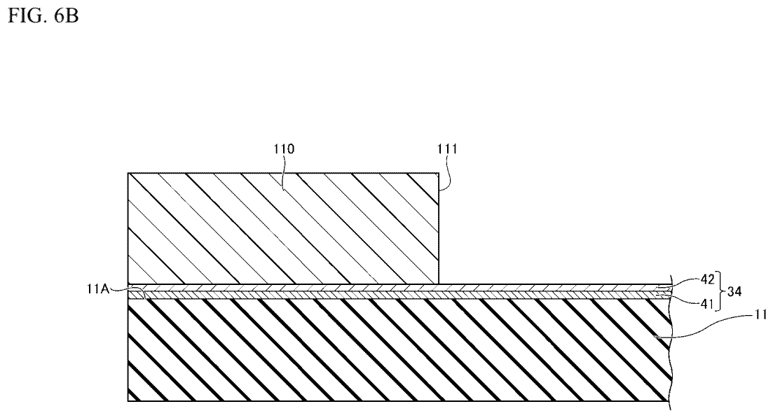

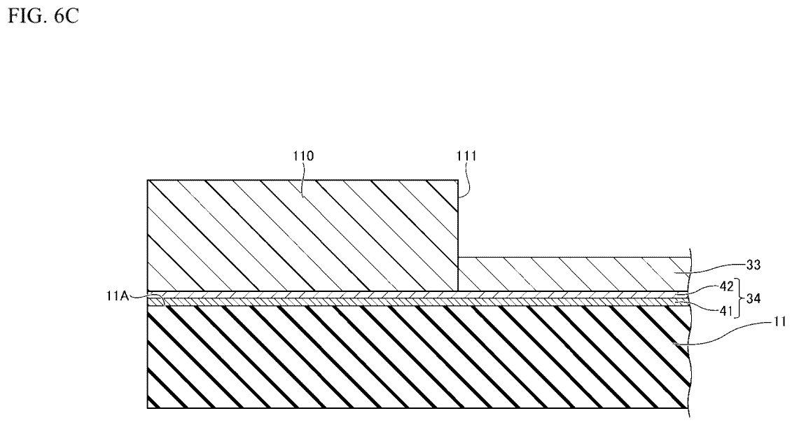

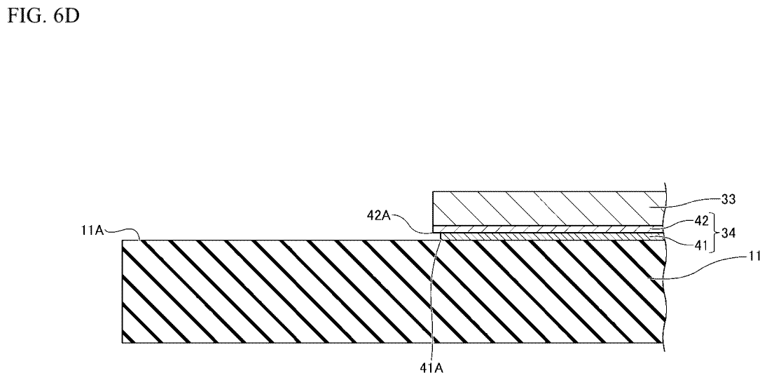

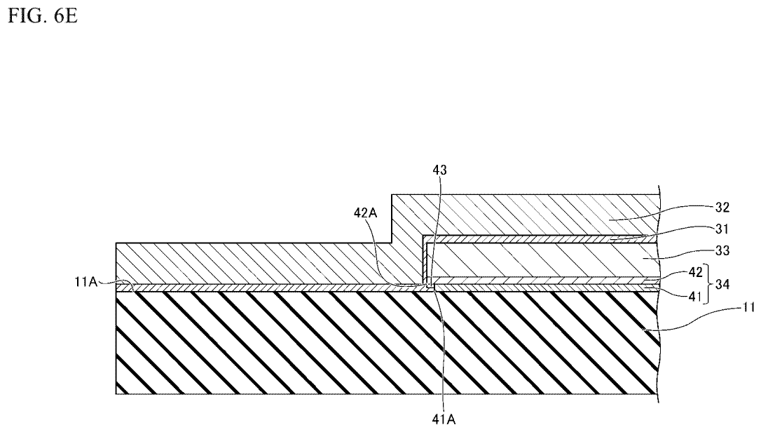

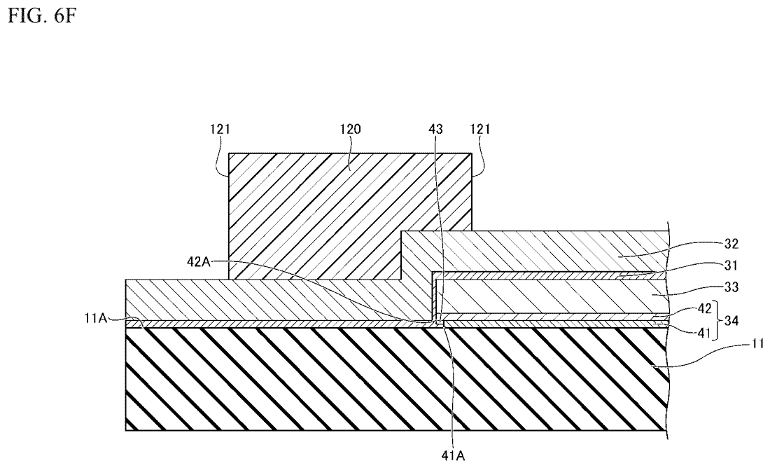

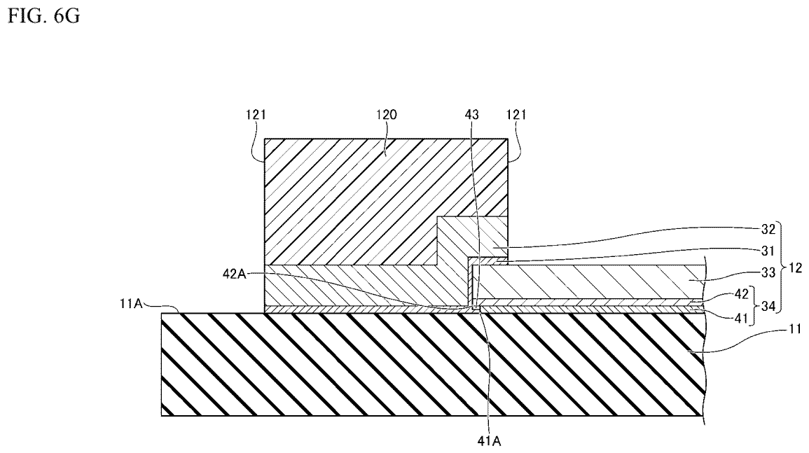

A method for manufacturing the light-emitting device according to the first embodiment is described. First, a method for manufacturing the substrate 10 is described. FIGS. 6A to 6G are cross-sectional views illustrating the method for manufacturing the substrate included in the light-emitting device according to the first embodiment.

First, as illustrated in FIG. 6A, a step of preparing the base 11 and disposing the second conductive layer 34 on the upper surface 11A of the base 11 is performed. In the step of disposing the second conductive layer 34, the first layer 41 including a nickel-chromium alloy is disposed on the upper surface 11A of the base 11, and the seed layer 42 including gold is disposed on an upper surface of the first layer 41. When the first layer 41 includes the nickel-chromium alloy, the first layer 41 and the seed layer 42 are preferably disposed by a sputtering method. When the first layer 41 and the seed layer 42 are disposed by the sputtering method, the heating temperature by the sputtering method is high, and film formation can be performed with strong energy. When the first layer 41 and the seed layer 42 are disposed by the sputtering method, unevenness tends to be formed on the surface of the first layer 41, but the unevenness is filled with the seed layer 42 and the surface of the seed layer 42 becomes substantially flat.

Subsequently, as illustrated in FIG. 6B, a step of disposing a mask 110 on the seed layer 42 is performed. The mask 110 has an opening 111 in a region where the conductive member 12 is to be formed. The mask 110 is, for example, a photoresist.

The mask 110 is not particularly limited, and can be formed by using a photoresist composition, a sheet-shaped resist (dry film resist), or the like commonly used in the technical field of light-emitting elements. Specifically, photoresist compositions made of various materials and classified into a novolac-diazonaphthoquinone (DNQ) photoresist, a positive photoresist, a negative photoresist, a chemical amplification type photoresist, a photo-crosslinking photoresist, a photopolymerization photoresist, and the like, or a dry film resist made of these photoresist compositions can be used as the mask 110. Any commercially available products of these photoresist compositions or the dry film resist can be used. Among these, the mask 110 is preferably formed by using a negative photoresist.

Examples of a method of forming the mask 110 by using a photoresist composition include a screen coating method, a spin coating method, a roll coating method, a laminator method, a dip coating method, and a spray coating method.

Subsequently, the mask 110 can be formed into a predetermined shape by using, for example, a photolithography method and an etching method. For example, when a negative photoresist is used, the mask 110 is exposed to light by using a mask having an opening with a desired shape in accordance with the opening 111.

The exposure amount is not particularly limited, and is preferably appropriately set in a range from about 10 mJ to 50 mJ. Before or after the exposure, baking can be performed at any temperature during any period of time.

Subsequently, the mask 110 is patterned into a predetermined shape by immersion development, spray development, or the like using a developer that dissolves a resist present in an unexposed portion of the mask 110.

The developer used in this step can be appropriately selected depending on the type of resist being used. Examples of the developer include tetramethylammonium hydroxide (TMAH) and tetrabutylammonium hydroxide (TBAH).

Subsequently, as illustrated in FIG. 6C, a step of disposing the gold layer 33 on the seed layer 42 inside the opening 111 is performed. The gold layer 33 can be disposed by an electrolytic plating method, a vapor deposition method, or the like. According to the electrolytic plating method, the gold layer 33 having a thickness of several μm can be easily disposed because a film formation rate is high. After the gold layer 33 is disposed, the mask 110 is removed. The first boundary 86 including the linear portion 86b or the curved portion 86c can be disposed by exposing the mask 110 to have the opening 111 having a shape corresponding to the linear portion 86b or the curved portion 86c in the step of disposing the gold layer 33.

Subsequently, as illustrated in FIG. 6D, a step of removing a portion of the second conductive layer 34 exposed from the gold layer 33 is performed. In the portion of the second conductive layer 34 exposed from the gold layer 33, the seed layer 42 and the first layer 41 can be removed by wet etching. When the first layer 41 is removed, a part of the outer edge of the first layer 41 overlapping the gold layer 33 in top view is also removed, so that a part of the lower surface of the seed layer 42 is exposed. The wet etching can be referred to as flash etching. The wet etching suppresses adjacent wirings from being electrically connected to each other via the second conductive layer 34 exposed from the gold layer 33. Accordingly, insulation can be ensured between the gold layers 33 of the adjacent wirings. In this way, in order to sufficiently ensure the insulation of the wiring on the base 11, the side etching of the first layer 41 is performed under conditions that facilitate the progression of the side etching. Thus, the end portion 41A of the first layer 41 is positioned on the inner side of the end portion of the gold layer 33 and the end portion 42A of the seed layer 42 in top view, so that a space is formed between the base 11 and the seed layer 42. In top view, the distance between the end portion 41A of the first layer 41 and the end portion 42A of the seed layer 42 is larger than 0 μm and smaller than 10 μm.

Subsequently, as illustrated in FIG. 6E, a step of disposing the first conductive layer 31 and the aluminum layer 32 on the base 11 and the gold layer 33 is performed. The first conductive layer 31 can be disposed by a sputtering method or the like, and the aluminum layer 32 can be disposed by a sputtering method, a vapor deposition method, or the like.

Since the distance between the upper surface 11A of the base 11 and the lower surface of the seed layer 42 is short, when the first conductive layer 31 is disposed by a sputtering method or the like, the sputtered particles forming the first conductive layer 31 have difficulty in going around to fill the space between the base 11 and the seed layer 42. Therefore, the gap 43 is formed between the base 11 and the seed layer 42. When the thickness of the first conductive layer 31 is equal to or greater than the thickness of the first layer 41, since the film of the first conductive layer 31 is continuous in the vicinity of the first boundary 86, the gap 43 is a space surrounded by the first conductive layer 31, the first layer 41, the seed layer 42, and the base 11. When the thickness of the first conductive layer 31 is less than the thickness of the first layer 41, there is a possibility that the first conductive layer 31 is interrupted in the vicinity of the first boundary 86 due to insufficient film formation or the like. When the first conductive layer 31 is interrupted due to insufficient film formation or the like, the gap 43 is a space surrounded by the aluminum layer 32, the first conductive layer 31, the first layer 41, the seed layer 42, and the base 11.

Subsequently, as illustrated in FIG. 6F, a step of disposing a mask 120 on the aluminum layer 32 is performed. The mask 120 covers a region where the first conductive layer 31 and the aluminum layer 32 are to be left, and has an opening 121 in the other regions. The mask 120 is, for example, a photoresist similar to that described above.

Subsequently, as illustrated in FIG. 6G, portions of the aluminum layer 32 and the first conductive layer 31 exposed from the mask 120 are removed. As a result, in a region where the second portion 82 of the conductive member 12 is to be formed, the gold layer 33 is exposed from the aluminum layer 32 and the first conductive layer 31. The portions of the aluminum layer 32 and the first conductive layer 31 exposed from the mask 120 can be removed by wet etching. Subsequently, the mask 120 is removed.

When the covering member 60 covers only at least a part of the conductive member 12 without contacting the light-emitting elements 20, an uncured resin is printed on the upper surface 11A of the base 11, applied by dispensing, or bonded in a sheet state, and then cured. Thus, the substrate 10 including the covering member 60 can be obtained.

By so doing, the substrate 10 including the base 11 and the conductive member 12 can be manufactured.

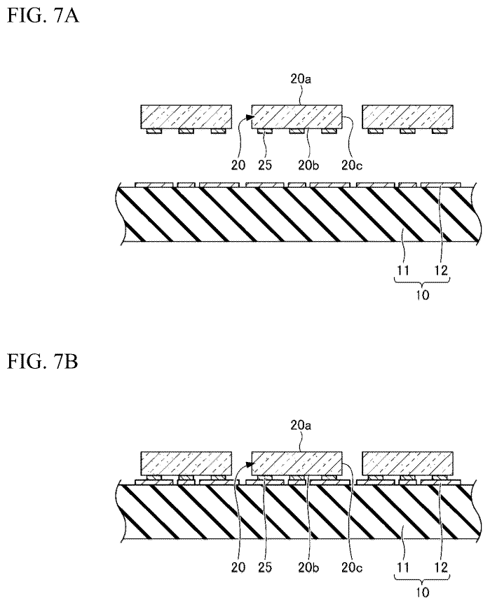

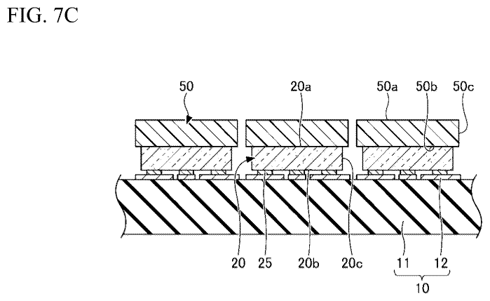

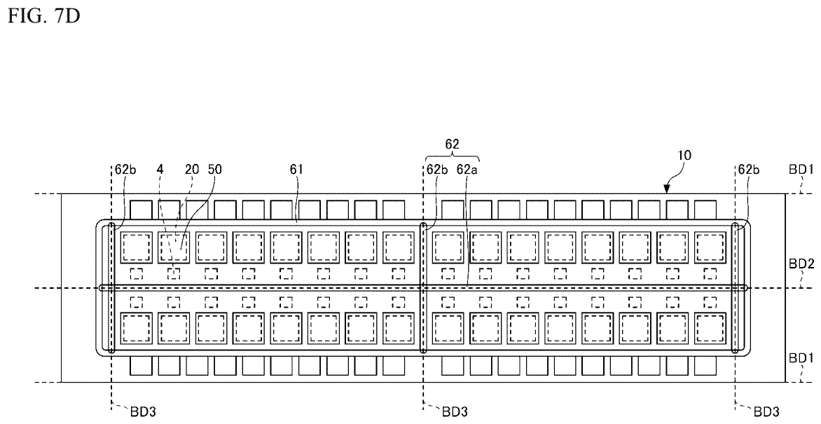

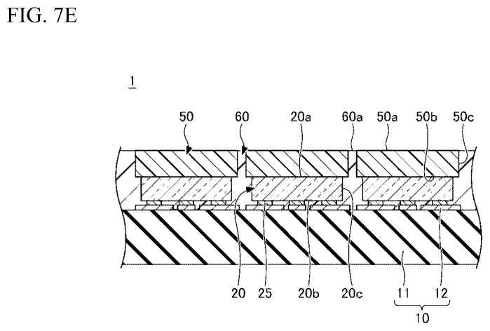

A light-emitting device is manufactured using the substrate 10. FIGS. 7A to 7C and 7E are schematic partial cross-sectional views for explaining a manufacturing process of the light-emitting device according to the first embodiment. FIG. 7D is a schematic top view for explaining the manufacturing process of the light-emitting device according to the first embodiment.

First, as illustrated in FIG. 7A, the substrate 10 and the light-emitting element 20 including the upper surface 20a, the lower surface 20b, and the plurality of lateral surfaces 20c continuous with the upper surface 20a and the lower surface 20b are prepared. In the example illustrated in FIG. 7A, a plurality of light-emitting elements 20 are prepared. Subsequently, as illustrated in FIG. 7B, the plurality of light-emitting elements 20 are disposed on the substrate 10. Each of the light-emitting elements 20 is, for example, flip-chip mounted on the substrate 10 via a gold bump, which is the conductive bonding member 25, with a surface on which electrodes are disposed facing the conductive member 12 side.

Subsequently, the light-transmissive member 50 is disposed on the light-emitting element 20. In the example illustrated in FIG. 7C, one light-transmissive member 50 is disposed on each of the plurality of light-emitting elements 20. In the first embodiment, the light-transmissive member 50 is disposed on the upper surface 20a of the light-emitting element 20 via an adhesive resin. Note that the light-transmissive member 50 can be disposed on the upper surface of the light-emitting element 20 by a direct bonding method such as pressure bonding, surface activation bonding, atomic diffusion bonding, or hydroxyl group bonding without the intervention of a bonding member such as an adhesive resin. In the present embodiment, a protective element 4 is disposed next to each of the light-emitting elements 20.

Subsequently, the covering member 60 that collectively covers the lateral surfaces 50c of the light-transmissive members 50 and the lateral surfaces 20c of the light-emitting elements 20 is disposed on the substrate 10. Specifically, an uncured resin to become the covering member 60 is disposed by dispensing. In FIG. 7D, only the external connecting portion 12a of the conductive member 12 is illustrated, and a wiring pattern extending from the external connecting portion 12a onto the base 11 is omitted. In FIG. 7D, a boundary line BD1, a boundary line BD2, and a boundary line BD3, which are virtual lines that define regions where a plurality of light-emitting devices 1 are to be formed, are indicated by broken lines. FIG. 7D illustrates an excerpt of a partial region of the substrate 10 before singulation.

In the present embodiment, eight light-emitting elements 20 and eight protective elements 4 are mounted per region where one light-emitting device is to be formed, which is defined by the boundary line BD1, the boundary line BD2 and the boundary line BD3. The boundary line BD1 and the boundary line BD2 are virtual lines that define the longitudinal direction of the region where the light-emitting device is to be formed, and the boundary line BD3 is a virtual line that defines the lateral direction of the region where the light-emitting device is to be formed. As illustrated by the arrangement locations of the external connecting portions 12a of the conductive members 12, the formation regions of the light-emitting devices arranged in the lateral direction (vertical direction in FIG. 7D) are disposed so that the orientation in the up-down direction alternately changes for each row. That is, in the present embodiment, regions where the light-emitting devices are to be formed are substantially line-symmetric with the boundary line BD2 as the axis of symmetry in plan view. Therefore, the light-emitting elements 20 are disposed on the substrate 10 to be substantially line-symmetric with the boundary line BD2 as the axis of symmetry.

In a region where each light-emitting device is to be formed, eight light-emitting elements 20 each having a substantially square shape in top view are arranged in a line in the longitudinal direction at a substantially central portion in the lateral direction. The eight protective elements 4 are disposed substantially at the center of each of the light-emitting elements 20 in the longitudinal direction (horizontal direction in FIG. 7D) and on the side opposite to the side where the external connecting portion 12a is provided with respect to each of the light-emitting elements 20 in the lateral direction (vertical direction in FIG. 7D).

First, as illustrated in FIG. 7D, an uncured resin forms a substantially rectangular frame surrounding the plurality of light-emitting elements 20 in top view. At this time, a first convex member 61 having a substantially rectangular shape is made of an uncured resin to include an outer edge of the first region 91 (that is, a region to be an outer edge of the covering member 60). Subsequently, a second convex member 62 overlapping the boundary line BD2 and the boundary line BD3 is made of an uncured resin. The second convex member 62 includes a second convex member 62a overlapping the boundary line BD2 and a second convex member 62b overlapping the boundary line BD3. Subsequently, as illustrated in FIG. 7E, an uncured resin is disposed in the vicinity of the outer periphery of the plurality of light-emitting elements 20. At this time, the uncured resin spreads by capillarity to cover the lower surface 20b of the light-emitting element 20 and the conductive bonding member 25. Subsequently, an uncured resin covers the lateral surfaces 50c of the light-transmissive members 50 and the lateral surfaces 20c of the light-emitting elements 20. At this time, the amount of the uncured resin is adjusted so that the upper surface of the uncured resin covering the lateral surfaces 20c of the light-emitting element 20 and the upper surface 50a of the light-transmissive member 50 are substantially flush with each other. Subsequently, the covering member 60 is formed by curing the uncured resin. Thus, as illustrated in FIG. 5A, the substrate 10 including the first region 91 where the covering member 60 is disposed and the second region exposed from the covering member 60 is formed. Finally, as illustrated in FIGS. 1 and 2, the substrate 10 and the covering member 60 are cut by a dicer along the boundary line BD2 and the boundary line BD3 to include a desired number of light-emitting elements 20, thereby obtaining individual light-emitting devices 1.

By so doing, the light-emitting device 1 according to the first embodiment can be manufactured.

### Light-Emitting Device According to Second Embodiment

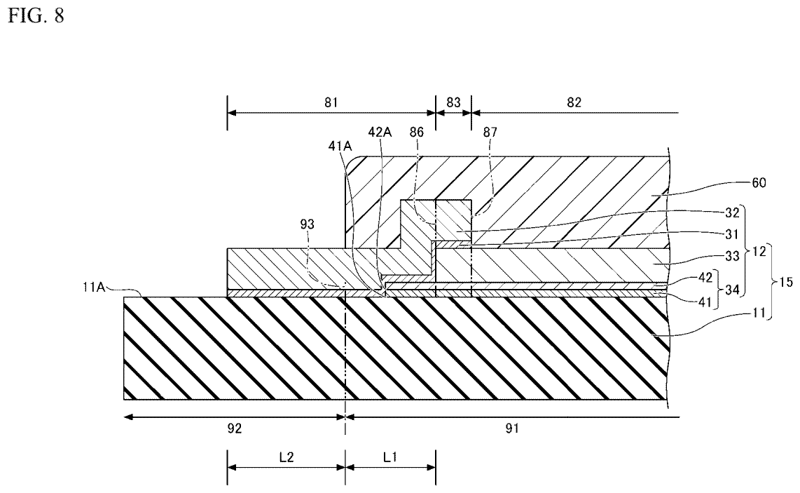

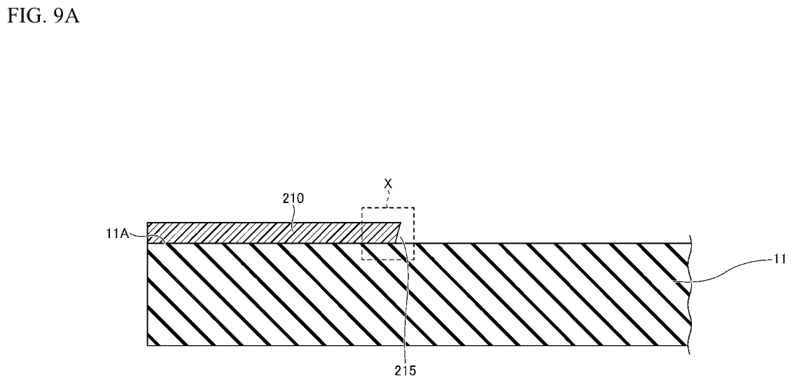

A description is given for the second embodiment. The second embodiment is different from the first embodiment mainly in a configuration of a substrate. FIG. 8 is a cross-sectional view schematically illustrating a substrate constituting a light-emitting device according to the second embodiment, and corresponds to a cross-sectional view taken along line V-V in FIG. 2.

As illustrated in FIG. 8, the light-emitting device according to the second embodiment includes a substrate 15 instead of the substrate 10. While the second conductive layer 34 is disposed only in the second portion 82 and the third portion 83 in the substrate 10, the second conductive layer 34 is disposed not only in the second portion 82 and the third portion 83 but also in a part of the first portion 81 in the substrate 15. That is, the end portion 41A of the first layer 41 is positioned in the first portion 81. In the second embodiment, the end portion 42A of the seed layer 42 is also positioned in the first portion 81. The first conductive layer 31 is in contact with the first layer 41 and the seed layer 42.

Since the first conductive layer 31 and the first layer 41 are in contact with each other, the substrate 15 of the second embodiment has no gap 43. Thus, regardless of the thickness of the first conductive layer 31, the occurrence of an interruption in the first conductive layer 31 in the vicinity of the first boundary 86 due to insufficient film formation or the like is reduced, and film continuity is easily obtained. Accordingly, the effect of reducing the occurrence of galvanic corrosion is high.

The other configurations of the substrate 15 are the same as the configurations of the substrate 10. Also in the second embodiment, the first boundary 86 can have a shape including one or more curved portions 86c having a curved shape in top view, as in the modified example of the first embodiment.

### Method for Manufacturing Light-Emitting Device According to Second Embodiment

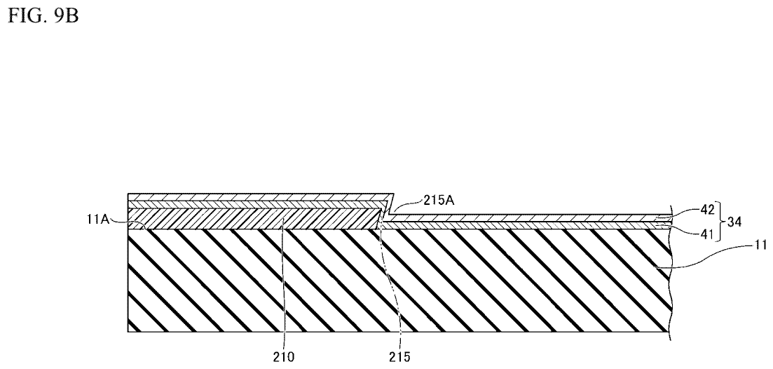

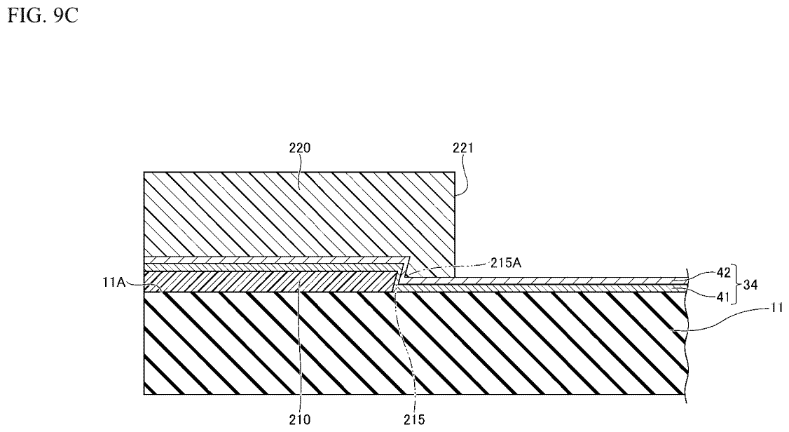

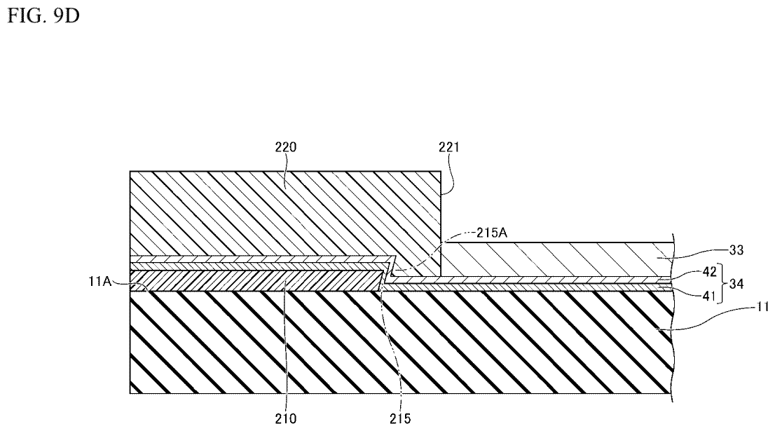

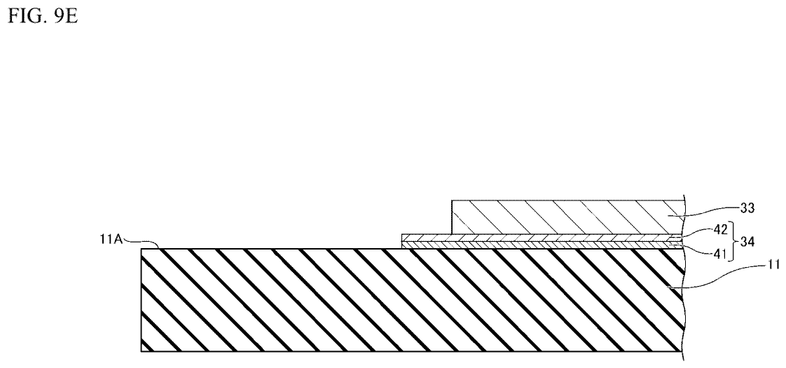

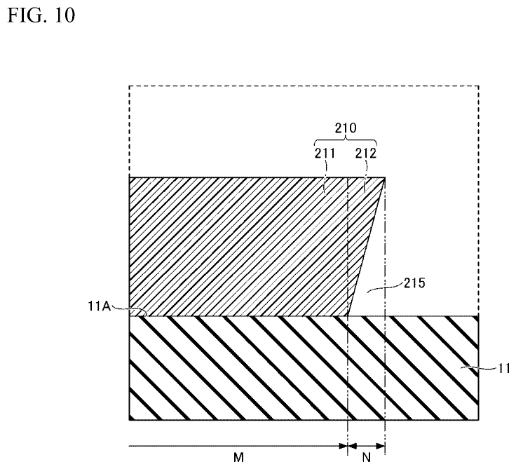

A method for manufacturing the light-emitting device according to the second embodiment is described. First, a method for manufacturing the substrate 15 is described. FIGS. 9A to 9E are schematic cross-sectional views illustrating the method for manufacturing the substrate included in the light-emitting device according to the second embodiment.

First, as illustrated in FIG. 9A, a step of preparing the base 11 and disposing a mask 210 on the base 11 is performed. The mask 210 is mainly different from the mask 110 in a cross-sectional shape. The mask 210 is formed so that its cross-sectional shape is an overhang shape (also referred to as a tapered shape). That is, the mask 210 is formed to have a cross-sectional shape of the mask 210 to have the width of the mask 210, in cross-sectional view (length in the direction parallel to the upper surface 11A of the base 11), decrease from an upper surface of the mask 210 toward a lower surface of the mask 210. FIG. 10 is a schematic enlarged cross-sectional view of region X in FIG. 9A. The region X includes a region M and a region N adjacent to the region M on the upper surface 11A of the base 11. The mask 210 is formed using a liquid photoresist. In the step of disposing the mask 210, the photoresist is exposed and developed so that the mask 210 has a main portion 211 that is in contact with the upper surface 11A of the region M and a protruding portion 212 that protrudes from the main portion 211 onto the region N without being in contact with the upper surface 11A of the region N. The maximum width of the protruding portion 212 protruding above the region N in the direction parallel to the upper surface 11A of the base 11 is in a range from 1 μm to 5 μm. Thus, a region 215 is formed between the upper surface 11A and the lateral surface (inclined surface) of the protruding portion 212, in other words, below the protruding portion 212.

By exposing and developing the photoresist, the mask 210 is formed in which the length (hereinafter, referred to as L1) of the lower surface of the mask 210 is shorter than the length (hereinafter, referred to as L2) of the upper surface of the mask 210 in the thickness-direction cross section of the base 11. That is, the length L1 of the lower surface of the mask 210 and the length L2 of the upper surface of the mask 210 satisfy L1<L2.

Subsequently, as illustrated in FIG. 9B, a step of disposing the second conductive layer 34 on the base 11 and the mask 210 is performed. The second conductive layer 34 can be disposed by a method similar to the method of the first embodiment. The thickness of the mask 210 from the upper surface 11A of the base 11 is as thin as several μm. Therefore, in the step of disposing the second conductive layer 34 on the base 11 and the mask 210, the material of the second conductive layer 34 goes around not only the upper surface 11A of the base 11 and the upper surface of the mask 210 but also the lateral surface (inclined surface) of the protruding portion 212, so that the second conductive layer 34 is disposed in the region 215 to be appropriately thin. Thus, a region 215A is formed along the upper surface 11A of the base 11 and the lateral surface (inclined surface) of the protruding portion 212. The term “appropriately thin thickness of the second conductive layer 34” as used herein means that the second conductive layer 34 disposed on the lateral surface of the protruding portion 212 has a thickness for forming the gold layer 33 by an electrolytic plating method in a step of disposing the gold layer 33 on the seed layer 42 inside an opening 221 to be described below, and has a thickness for removing the second conductive layer 34 disposed on the lateral surface of the protruding portion 212 in a step of removing a part of the second conductive layer 34, the mask 210, and a mask 220 to be described below. The thickness of the second conductive layer 34 disposed on the lateral surface of the protruding portion 212 is preferably in a range from 0.001 μm to 0.1 μm, for example.

Subsequently, as illustrated in FIG. 9C, a step of disposing the mask 220 on the second conductive layer 34 is performed. The mask 220 has the opening 221 in a region where the conductive member 12 is to be formed. The mask 220 is formed using a photoresist of a dry film. The mask 220 is formed so that an outer edge of the mask 220 is positioned outside an outer edge of the mask 210 in top view, so that the mask 210 is not exposed from the mask 220. For example, in top view, a distance between the outer edge of the mask 220 and the outer edge of the mask 210 is in a range from 3 μm to 8 μm. By performing vacuum drawing when the dry film is used, air between the mask 210/the second conductive layer 34 and the mask 220 can be removed, and the mask 220 can also be disposed in the region 215A. As the mask 210, a liquid resist can be used instead of the dry film. In the step of disposing the mask 220, the photoresist is exposed and developed so that the photoresist disposed on the upper surface of the second conductive layer 34 and the photoresist disposed on the lateral surface of the second conductive layer 34 in the region 215A remain. Thus, the second conductive layer 34 disposed on the upper surface 11A is exposed from the mask 220.

Subsequently, as illustrated in FIG. 9D, the step of disposing the gold layer 33 on the seed layer 42 inside the opening 221 is performed. The gold layer 33 can be disposed by a method similar to the method of the first embodiment. At this time, since the first layer 41 and the seed layer 42 are disposed in the region 215 and the mask 220 is disposed in the region 215A, the gold layer 33 is not formed in the region where the region 215 and the region 215A were present. In addition, by disposing the mask 210 not to be exposed from the mask 220, the shape of the end portion of the gold layer 33 can be adjusted.

Subsequently, as illustrated in FIG. 9E, the step of removing a part of the second conductive layer 34, the mask 210, and the mask 220 is performed. In this step, the mask 210, the second conductive layer 34 disposed on the upper surface of the mask 210, the second conductive layer 34 disposed on the lateral surface of the mask 210 (in other words, the lateral surface of the protruding portion 212), the mask 220 disposed on the mask 210, and the mask 220 disposed in the region 215A are removed.

Subsequently, similarly to the first embodiment, the step of disposing the first conductive layer 31 and the aluminum layer 32 on the base 11 and the gold layer 33 and the subsequent steps (refer to FIGS. 6E to 6G) are performed. By so doing, the substrate 15 can be manufactured.

Subsequently, by performing the same steps as those of the first embodiment (see FIGS. 7A to 7E) by using the substrate 15 instead of the substrate 10, the light-emitting device according to the second embodiment can be manufactured.

Preferred embodiments and the like have been described in detail above. However, the disclosure is not limited to the above-described embodiments and the like, and various modifications and substitutions can be made to the above-described embodiments and the like without departing from the scope described in the claims.

1. A substrate comprising:
a base including a primary surface;
a conductive member disposed on the primary surface; and
a covering member,
wherein the conductive member comprises:
a first portion including a first conductive layer and an aluminum layer layered in order from a bottom of the conductive member;
a second portion including a gold layer on an uppermost surface of the second portion of the conductive member; and
a third portion including the gold layer, the first conductive layer, and the aluminum layer layered in order from the bottom of the conductive member, and
wherein the covering member covers a first boundary, which is a boundary between the first portion and the third portion, and a second boundary, which is a boundary between the second portion and the third portion.

2. The substrate according to claim 1, wherein an ionization tendency of the first conductive layer is lower than an ionization tendency of the aluminum layer.

3. The substrate according to claim 1,
wherein the base includes a nitride ceramic,
wherein the conductive member includes a second conductive layer between the gold layer and the base, and
wherein the second conductive layer includes a first layer comprising nickel and chromium.

4. The substrate according to claim 3,
wherein the first conductive layer comprises at least one of titanium or ruthenium, and
wherein a gap is arranged between the first conductive layer and the first layer.

5. The substrate according to claim 4, wherein an end portion of the first layer is positioned in the third portion.

6. The substrate according to claim 3, wherein an end portion of the first layer is positioned in the first portion.

7. The substrate according to claim 3, wherein a thickness of the first conductive layer is smaller than a thickness of the second conductive layer.

8. The substrate according to claim 1,
wherein the base comprises a nitride ceramic,
wherein the first conductive layer comprises at least one of titanium or ruthenium, and
wherein the first conductive layer and the base are in contact with each other.

9. The substrate according to claim 1, wherein a thickness of the third portion is greater than a thickness at an outer edge of the first portion and a thickness of the second portion.

10. The substrate according to claim 1, wherein, in top view, an area of the third portion is smaller than an area of the first portion.

11. The substrate according to claim 1,
wherein the primary surface of the base comprises:
a first region in which the covering member is disposed; and
a second region exposed from the covering member, and
wherein a distance between the first boundary and a third boundary, which is a boundary between the first region and the second region, is 10 μm or more.

12. The substrate according to claim 11, wherein, in top view, a distance from the third boundary to an outer edge of the first portion is 100 μm or more.

13. The substrate according to claim 1, wherein, in top view, the first boundary includes a curved portion.

14. A light-emitting device comprising:
the substrate according to claim 1; and
a light-emitting element provided on the substrate,
wherein the light-emitting element is connected to the gold layer in the second portion.

15. The light-emitting device according to claim 14, wherein the covering member covers the light-emitting element.

16. A substrate, comprising:
a base including a primary surface; and
a conductive member disposed on the primary surface,
wherein the conductive member comprises:
a first portion including a first conductive layer and an aluminum layer layered in order from a bottom of the conductive member;
a second portion including a gold layer on an uppermost surface of the second portion of the conductive member; and
a third portion including the gold layer, the first conductive layer, and the aluminum layer layered in order from the bottom of the conductive member, and in top view, an area of the third portion is smaller than an area of the first portion,
wherein the conductive member comprises a second conductive layer including a first layer between the gold layer and the base, and
wherein a gap is arranged between the first conductive layer and the first layer.

17. The substrate according to claim 16, wherein an end portion of the first layer is positioned in the third portion.

18. A light-emitting device comprising:
the substrate according to claim 16; and
a light-emitting element provided on the substrate,
wherein the light-emitting element is connected to the gold layer in the second portion.
